(19) United States
(12) Patent Application Publication
(10) Pub. No.: US 2008/0315951 A1
(43) Pub. Date: Dec. 25, 2008

(54) CLASS AB DIFFERENTIAL AMPLIFIER WITH OUTPUT STAGE COMMON MODE FEEDBACK

(76) Inventors: JEFFREY RYSINSKI, Pasadena, CA (US); Sanjayan Vinayagamoorthy, Pasadena, CA (US)

Correspondence Address: DORSEY & WHITNEY LLP;INTELLECTUAL PROPERTY DEPARTMENT, SUITE 3400, 1420 FIFTH AVENUE, SEATTLE, WA, 98101, US

(21) Appl. No.: 11/765,211

(22) Filed: Jun. 19, 2007

(51) Int. Cl. H03F 3/45

(52) U.S. Cl. 330/258; 330/261

(57) ABSTRACT

A differential amplifier includes an output stage, a first common mode feedback circuit; and a current source. The output stage includes first and second complimentary output terminals. The first common mode feedback circuit is operable to determine an average voltage across the first and second complimentary output terminals. The current source is coupled to the output stage, and the common mode feedback circuit is operable to control the current source based on the average voltage. A method includes determining an average voltage across a positive output terminal and a negative output terminal of a differential amplifier output stage and controlling current injected into the output stage based on the average voltage.

### TECHNICAL FIELD

Embodiments of the invention relates generally to differential amplifiers and, more particularly, to a class AB differential amplifier with output stage common mode feedback.

Differential amplifiers are commonly used electronic devices. Generally, a differential amplifier multiplies the difference between two input signals by a constant gain factor. In a differential amplifier, noise is usually impressed on both the data signal line and its complementary data signal line. Since the differential amplifier responds to differences in the voltage applied between its differential inputs, it does not significantly respond to noise signals applied to both inputs. Thus, a potential advantage of using a differential amplifier to amplify the complimentary data signals is that it will often be less sensitive to noise. Thus, differential amplifiers display a high degree of immunity to common mode signals such as noise.

During operation, the average voltage of the positive and negative terminals is typically maintained at a constant level. Due to device imperfections, differential amplifier outputs could tend to drift high or low without compensation. One technique for providing such compensation is the use of a common mode feedback (CMFB) circuit to bias one or more transistors to stabilize the circuit. Generally, a common mode feedback circuit monitors the average positive and negative output voltages and adjusts a bias voltage applied to a transistor in the circuit to maintain a stable steady state average voltage.

With class AB differential amplifiers currents may change significantly in magnitude during transitions, and such transitions may occur quickly. Because common mode feedback is by nature a feedback approach, the circuits require time to settle to a steady state value. Conventional common mode feedback compensation techniques can create common mode transients. To avoid the effects of such transients, a delay may be imposed to allow the common mode to settle. However, this delay impedes the speed of the amplifier, thus negating some of the advantages a class AB amplifier was intended to provide.

Turning now to FIG. 1, a conventional class AB differential amplifier circuit 100 is illustrated. The circuit 100 includes an input stage 105 and output stages 110A, 110B. For ease of illustration, the input stage 105 is modeled as a single stage amplifier, the construct of which is known to those of ordinary skill in the art. The input stage 105 receives complimentary input signals, INP and INN and generates complimentary preliminary output signals VOUTP and VOUTN. In the following designation, the output stage 110A is associated with a positive output terminal 115A, and the output stage 110B is associated with a negative output terminal 115B. Individual components associated with the positive output stage 110A have “A” designators and components associated with the negative output stage 1I OB have “B” designators. The output stages 110A, 110B are complimentary in nature and operate similarly. The output stages 110A, 110B receive the output signals from the input stage 105 and increase the gain to provide amplified output signals, OUTN and OUTP at the output terminals 115A, 115B.

The output stage 110A includes a reference leg 120A having a p-type transistor 125A and a diode-coupled n-type transistor 130A and a load leg 135A having a p-type transistor 140A and an n-type transistor 145A. The positive output terminal 115A is coupled to the load leg 135A. The output stage 110B includes similar devices with “B” designators.

In the output stage 110A, current in the reference leg 120A is mirrored in the load leg 135A. If a high magnitude sourcing current seen at the positive output terminal 115A the transistor 140A sources this current, and a large sinking current is present in the transistor 145B in the load leg 135B associated with the negative terminal 115B. Assume that due to signals present at the inputs of the input stage 105, VOUTP goes low and VOUTN goes high. As a result, a large current is sourced by the transistor 140A, which is seen in the OUTP signal at the positive output terminal 115A. Since VOUTN goes high, the transistors 140B and 125A effectively turn off (i.e., source no or very little current). Since the transistor 125B is the same size as the transistor 140A, it too will source a current that is as large as the current in the transistor 140A. This current gets reflected by the transistor 130B to transistor 145B. Hence, the same sinking current seen at the negative terminal 115B corresponds to the sourcing current seen at the positive terminal 115A. An opposite relationship exists when VOUTP goes high and VOUTN goes low, as is know to those of ordinary skill in the art.

A conventional CMFB technique is not effective for the class AB differential amplifier 100 of FIG. 1. One conventional approach is to split the transistors 145A and 145B into two parallel devices. For purposes of this illustration assume the two transistors are equal in size. Again, suppose that VOUTP goes low and VOUTN goes high. A large current is sourced by the transistor 140A into the positive output terminal 115A. This same large current is sourced by the transistor 125B and is reflected by transistor 130B. However, in this case, since the transistor 145B is half its original size, the current is only half as large. Thus, the current sunk is not the same as current sourced. This imbalance will cause the common mode voltage of the output voltage to change during the transient.

Note that the common mode voltage is defined as the average of OUTP and OUTN. If OUTP rises the same as the OUTN lowers, then the common mode voltage does not change. This is the case when the sourcing current and the sinking current are equal. When they are different, the average value of OUTP and OUTN will change and so will the common mode voltage. If the common mode voltage changes, the common mode feedback (CMFB) signal will also change to attempt to compensate for this. The CMFB circuit is a circuit network that tries to ensure that the common mode voltage is well defined. In differential circuits, the common mode voltage is controlled since process parameters can cause variations in the devices that make up the amplifier. The CMFB signal (i.e., the output of the CMFB network) is a low frequency signal that typically does not vary once it has reached its steady state value.

Thus, using traditional CMFB techniques in the amplifier of FIG. 1, the CMFB signal associated with the output stages 115A, 115B will change every time the sourcing and sinking currents are not the same. This occurs every time the inputs to amplifier change, as described above. Thus, the CMFB signal would change as quickly as the inputs. This situation is impractical to implement as the CMFB scheme would need to react extremely quickly. CMFB signals are defined as slow response signals that should react according to process variation or temperature variation, not changes to input signals.

### BRIEF DESCRIPTION OF THE SEVERAL VIEWS OF THE DRAWINGS

The embodiments of the invention will hereafter be described with reference to the accompanying drawings, wherein like reference numerals denote like elements, and:

FIG. 1 is a circuit diagram of a prior art class AB differential amplifier; and

FIG. 2 is a circuit diagram of a class AB differential amplifier including output stage common mode feedback control in accordance with an illustrative embodiment of the present invention.

### DETAILED DESCRIPTION OF EMBODIMENTS OF THE INVENTION

One or more specific embodiments of the present invention are described below. It is specifically intended that the present invention not be limited to the embodiments and illustrations contained herein, but include modified forms of those embodiments including portions of the embodiments and combinations of elements of different embodiments as come within the scope of the following claims. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. Nothing in this application is considered critical or essential to the present invention unless explicitly indicated as being “critical” or “essential.”

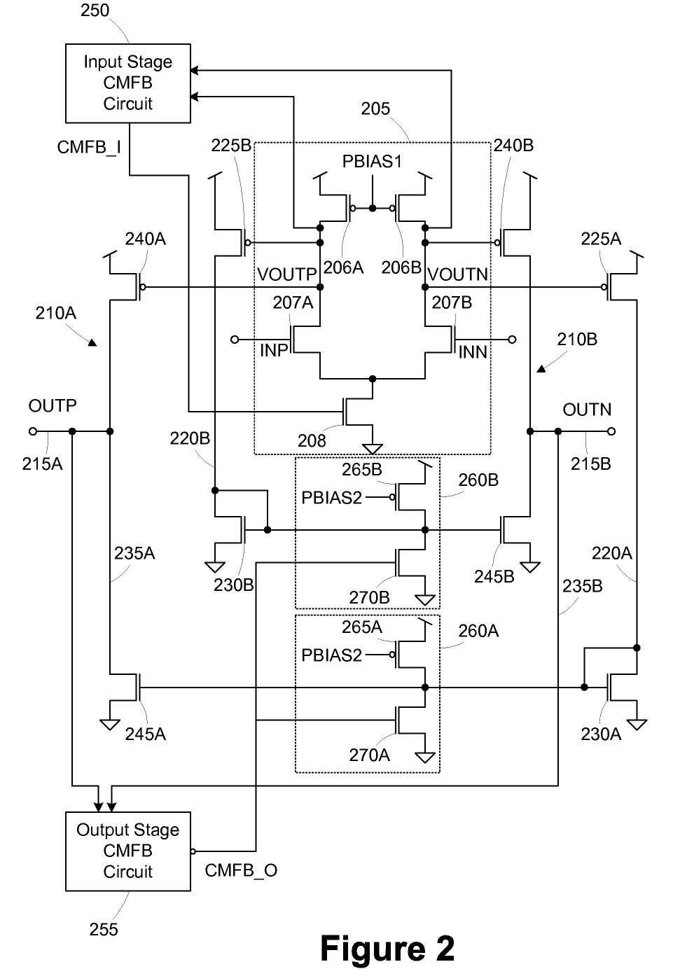

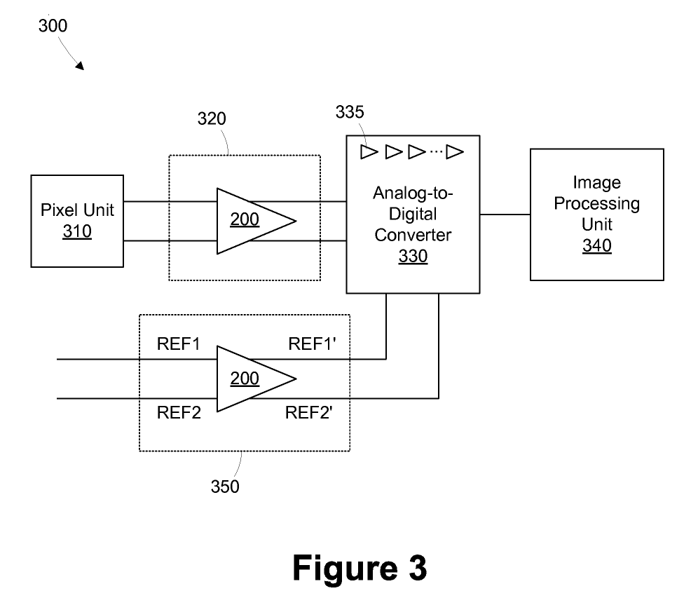

Referring now to the drawings wherein like reference numbers correspond to similar components throughout the several views and, specifically, referring to FIG. 2, embodiments of the present invention shall be described in the context of a differential amplifier 200 circuit. In the circuit 200 described below various devices are illustrated as being p-type or n-type transistors. The application of the techniques described herein are not limited to the specific device types illustrated, as those of ordinary skill in the art will appreciate that similar circuits that accomplish similar functions using alternative device types may be used.

The differential amplifier circuit 200 includes an input stage 205, output stages 210A, 210B, an input stage common mode feedback (CMFB) circuit 250, an output stage CMFB circuit 255, and current sources 260A, 260B. As will be described in greater detail below, the output stage CMFB circuit 255 controls the current sources 260A, 260B to provide common mode feedback control for the output stages 210A, 210B that is not sensitive to dynamic changes in the input signals.

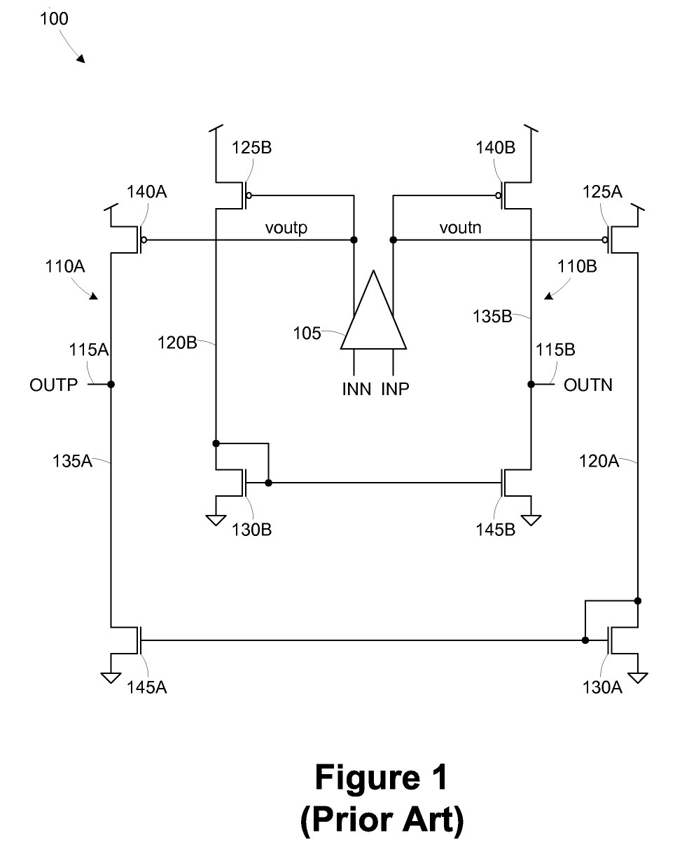

The operation of the elements having “200” series reference numerals is similar to the operation of the corresponding “100 series” elements described in reference to the prior art differential amplifier circuit 100 of FIG. 1. The input stage 205 receives complimentary input signals, INP and INN and generates complimentary preliminary output signals VOUTP and VOUTN. The output stage 210A is associated with a positive output terminal 215A, and the output stage 210B is associated with a negative output terminal 215B. Individual components associated with the positive output stage 210A have “A” designators and components associated with the negative output stage 210B have “B” designators. The output stages 210A, 210B are complimentary in nature and operate similarly. The output stages 210A, 210B receive the output signals from the input stage 205 and increase the gain to provide amplified output signals, OUTN and OUTP at the output terminals 215A, 215B.

The input stage 205 is a conventional single stage differential amplifier that includes p-type transistors 206A, 206B, n-type transistors 207A, 207B, and a CMFB bias transistor 208 controlled by the input stage CMFB circuit 250. The operation of the input stage 205 is conventional and known to those of ordinary skill in the art. The input stage CMFB circuit 250 determines an average value of the values of VOUTP and VOUTN to determine the common mode voltage and adjusts the bias voltage applied to the transistor 208 to balance the input circuit using a bias signal CMFB_{—}1. The bias, PBIAS1, applied to the transistors 206A, 206B is typically a fixed voltage, however, it is contemplated that the bias signal applied to the transistor 208 may be fixed and the bias signal applied to the transistors 206A, 206B may be controlled by the input stage CMFB circuit 250.

The construct and operation of the input stage CMFB circuit 250 are well known to those of ordinary skill in the art, and are not described in greater detail herein. Typically, the output value of the input stage CMFB circuit 250 does not change significantly once a steady state condition is achieved. The application of the techniques described herein is not limited to a particular embodiment of the input stage CMFB circuit 250, as various topologies are known in the art for generating a bias signal proportional to the difference between the average value of the VOUTP and VOUTN signals and a predetermined reference voltage.

The output stage 210A includes a reference leg 220A having a p-type transistor 225A and a diode-coupled n-type transistor 230A and a load leg 235A having a p-type transistor 240A and an n-type transistor 245A. The positive output terminal 215A is coupled to the load leg 235A. The transistors 240A, 245A in the load leg 235A may be sized larger than the transistors 225A, 230A in the reference leg 220A to increase the current gain of the differential amplifier 200. The output stage 210B includes similar devices with “B” designators. Again, the operation of the conventional portions of the differential amplifier circuit 200 is known in the art and is not described in detail herein.

The output stage CMFB circuit 255 determines an average value of the OUTP and OUTN signals to determine the common mode voltage and adjusts the bias voltage applied to the current sources 260A, 260B to balance the output circuit. The output stage CMFB circuit 255 may be a conventional CMFB circuit with the exception that the output is inverted. Hence, the bias signal is inversely proportional to the difference between the average values of the OUTP and OUTN signals and a predetermined reference voltage. Again, the application of the techniques described herein is not limited to a particular construction of the output stage CMFB circuit 255.

The current source 260A includes a p-type transistor 265A and an n-type transistor 270A. The current source 260B includes similar components with “B” designators. The bias, PBIAS2, applied to the transistors 265A, 265B is typically a fixed voltage. The output stage CMFB circuit 255 generates a bias signal, CMFB_O, for controlling the transistors 270A, 270B. Again, it is contemplated that the control scheme may be reversed and the bias signal applied to the transistors 270A, 270B may be fixed and the bias signal applied to the transistors 265A, 265B may be controlled by the output stage CMFB circuit 255. Moreover, the specific circuit used to implement the current sources 260A, 260B may vary.

The operation of the CMFB technique is described with reference to the output stage 210A and the current source 260A. Initially, the transistors 265A and 270A are biased to carry equal current in nominal conditional. When the average output voltage (i.e., (OUTP+OUTN)/2) voltage is higher than the output common mode voltage, the output stage CMFB circuit 255 lowers the CMFB_O bias signal resulting in a higher current in the transistor 265A than in the transistor 270A. This extra current flows through the transistor 230A and is mirrored in the transistor 245A which allows the transistor 245A to pull down the output terminal 215A.

Complimentary behavior occurs when the average output voltage is lower than the common mode voltage. The output stage CMFB circuit 255 raises the CMFB_O bias signal causing the transistor 270A to sink additional current. This current is pulled from the transistor 230A, which is mirrored in the transistor 245A causing the transistor 245A to pull up the output terminal 215A.

During transitions of the input signals, the input stage 205 generates a change in the current flowing through the transistor 230A. This current increase results in a voltage increase across the transistor 230A. Because the transistors 265A, 265B have reasonably high output impedances, they have a negligible effect on the dynamic current through the transistor 230A. As a result, the common mode voltage does not change appreciably during transitions in the input signals.

The differential amplifier 200 of FIG. 2 has numerous applications. One particular application is described below with reference to FIG. 3, however, the application of the differential amplifier 200 is not limited to any particular embodiment described herein. The differential amplifier 200 is a fundamental circuit element that may be employed in a wide variety of analog and mixed signal applications.

Turning now to FIG. 3, a simplified block diagram of an optical system 300 employing the differential amplifier 200 of FIG. 2 is provided. The optical system 300 includes a pixel unit 310 for collecting optical data, a gain unit 320 for increasing the gain of the signal provided by the pixel unit 310, an analog-to-digital converter (ADC) 330 for generating a digital word indicative of the intensity of the light determined by the pixel unit 310, an image processing unit 340 for processing the pixel data, and a reference voltage unit 350 for providing reference voltages to the ADC 330. The entities of the optical system 300 may be formed on a common device substrate or within a common package. Alternatively the entities may be separate devices. For example, the pixel unit 310, gain unit 320, ADC 330, and reference voltage unit 350 may be formed on a common substrate packaged as an optical sensor. The optical sensor may include external connections to the image processing unit 340.

Typically, the pixel unit 310 outputs an analog signal representing the intensity of light collected through a camera lens or aperture. The optical system 300 typically includes many pixel units 310, although only one is illustrated. The gain unit 320 depicted in the system 300 is optional and thus may not be present in all embodiments. The devices in the differential amplifier 200 may be sized, as described above, to provide a level of gain for amplifying the signal provided by the pixel unit 310.

In converting the analog input generated by the pixel unit 310, the ADC 330 employs reference voltages that specify the upper and lower limits expected in the signal. For example, the ADC 330 may be used to convert the pixel output, which is generally a voltage between 0.4V to 1.4V into a digital word, usually 10-12 bits in length. Hence, 0.4V represents code 0 (decimal) and 1.4V represents code 1023 (decimal). Since the pixel output voltages lie between 0.4V and 1.4V, then a 10 bit ADC 330 will convert these voltages to a digital word between 0 and 1023. If the ADC 330 operates using 12 bits, the digital output is between 0 and 4095, but the pixel output is still between 0.4 and 1.4V. The magnitudes of the reference voltages may vary depending on the particular application. The reference voltage unit 350 receives reference signal voltages, REF1, REF2 from a power source (not shown) and employs the differential amplifier 200 to generate ADC reference voltages, REF1′ and REF2′, for providing to the ADC 330. The differential amplifier 200 effectively isolates the ADC 330 from the voltage source, thereby reducing the effects of switching in the ADC 330 on the source.

Another application of the differential amplifier 200 is in the ADC 330. Typically, the ADC 330 includes one stage 335 for each output bit (e.g., 10 or 12 bits). Each stage 335 includes a differential amplifier 200 that receives reference voltage inputs that define the voltage limits to which the particular stage responds to for setting its associated bit.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

We claim:

1. A differential amplifier, comprising:
an output stage having first and second complimentary output terminals; and
a first common mode feedback circuit operable to determine an average voltage across the first and second complimentary output terminals; and
a current source coupled to the output stage, wherein the common mode feedback circuit is operable to control the current source based on the average voltage.

2. The amplifier of claim 1, further comprising an input stage coupled to the output stage, wherein the output stage comprises a first output stage coupled to the input stage and including the first complimentary output terminal and a second output stage coupled to the input stage and including the second complimentary output terminal, and the current source comprises a first current source coupled to the first output stage and a second current source coupled to the second output stage.

3. The amplifier of claim 2, wherein the first output stage includes a first reference leg coupled to the input stage and a first load leg coupled to the first complimentary output terminal, and the first current source is coupled between the reference leg and the load leg.

4. The amplifier of claim 3, wherein the first reference leg comprises a first transistor having a gate terminal coupled to a first terminal of the input stage and a diode-coupled second transistor coupled to the first transistor, the first load leg includes a third transistor having a gate terminal coupled to a second terminal of the input stage and a fourth transistor coupled to the third transistor, and the first complimentary output terminal is coupled between the third and fourth transistors.

5. The amplifier of claim 3, wherein the second output stage includes a second reference leg coupled to the input stage and a second load leg coupled to the second complimentary output terminal, and the second current source is coupled between the reference leg and the load leg.

6. The amplifier of claim 1, wherein the current source comprises a first transistor having a first conductivity type and a second transistor having a second conductivity type different than the first conductivity type, wherein the first transistor is coupled to receive a fixed bias voltage and the second transistor is coupled to receive a control signal from the first common mode feedback circuit.

7. The amplifier of claim 1, further comprising:
an input stage coupled to the output stage and including first and second intermediate output terminals;
a bias transistor coupled to the input stage; and
a second common mode feedback circuit operable to determine an average voltage across the first and second intermediate output terminals and control the input bias transistor based thereon.

8. A differential amplifier, comprising:
an input stage having first and second input terminals and first and second intermediate output terminals;
a first output stage coupled to the first and second intermediate output terminals and having a positive output terminal;
a first current source coupled to the first output stage;
a second output stage coupled to the first and second intermediate output terminals and having a negative output terminal;
a second current source coupled to the second output stage;
a first common mode feedback circuit operable to determine an average voltage across the positive output terminal and the negative output terminal control the first and second current sources based thereon.

9. The amplifier of claim 8, wherein the first output stage comprises a first reference leg coupled to the first intermediate output terminal and a first load leg coupled to the positive output terminal, and the second output stage comprises a second reference leg coupled to the second intermediate output terminal and a second load leg coupled to the negative output terminal.

10. The amplifier of claim 9, wherein the first reference leg comprises a first transistor having a gate terminal coupled to the first intermediate output terminal and a diode-coupled second transistor coupled to the first transistor, the first load leg includes a third transistor having a gate terminal coupled to the second intermediate output terminal and a fourth transistor coupled to the third transistor, and the positive output terminal is coupled between the third and fourth transistors.

11. The amplifier of claim 10, wherein the first current source is coupled between the load leg and the reference leg, and the first common mode feedback circuit is operable to control an amount of current injected by the first current source into the reference leg based on the average voltage.

12. The amplifier of claim 8, wherein the first common mode feedback circuit is operable to control an amount of current injected by the first current source into the output stage reference leg based on a difference between the average voltage and a reference voltage.

13. The amplifier of claim 12, wherein the first common mode feedback circuit is operable to generate a bias signal inversely proportional to the difference, and the current source is coupled to the common mode feedback circuit to receive the bias signal.

14. The amplifier of claim 8, further comprising:
a bias transistor coupled to the input stage; and
a second common mode feedback circuit operable to determine an average voltage across the first and second intermediate output terminals and control the bias transistor based thereon.

15. A method, comprising:
determining an average voltage across a positive output terminal and a negative output terminal of a differential amplifier output stage;
controlling current injected into the output stage based on the average voltage.

16. The method of claim 15, wherein controlling the current further comprises controlling a current source coupled to the output stage.

17. The method of claim 16, wherein the current source comprises a first transistor having a first conductivity type and a second transistor having a second conductivity type, controlling the current source comprises providing a fixed bias signal to a gate of the first transistor and controlling a bias signal provided to the second transistor based on the average voltage.

18. The method of claim 15, wherein controlling the current further comprises:
determining a difference between the average voltage and a reference voltage; and
generating a bias signal for applying to a current source coupled to the output stage based on the difference.

19. The method of claim 18, wherein generating the bias signal comprises generating the bias signal inversely proportional to the difference.

20. An imaging system, comprising:
a pixel unit operable to generate a first signal having an upper limit and a lower limit;
a gain unit coupled to the pixel unit;
an analog-to-digital converter coupled to the gain unit and operable to digitize the first signal; and
a reference voltage circuit operable to generate a first reference voltage corresponding to the upper limit and a second reference voltage corresponding to the lower limit, wherein at least one of the gain unit, the analog-to-digital converter, or the reference voltage circuit includes a differential amplifier comprising:
an input stage;
an output stage coupled to the input stage, the output stage having a positive output terminal and a negative output terminal; and
a first common mode feedback circuit operable to determine an average voltage across the positive output terminal and the negative output terminal; and
a current source coupled to the output stage, wherein the common mode feedback circuit is operable to control the current source based on the average voltage.
